(19) United States
(12) Patent Application Publication
(10) Pub. No.: US 2025/0306059 A1
(43) Pub. Date: Oct. 2, 2025

(54) PROBER, AND WAFER COOLING METHOD

(71) Applicant: TOKYO SEIMITSU CO., LTD., Tokyo (JP)

(72) Inventor: Hiroo TAMURA, Tokyo (JP)

(21) Appl. No.: 19/091,348

(22) Filed: Mar. 26, 2025

(30) Foreign Application Priority Data
Mar. 26, 2024 (JP) 2024-048922

(51) Int. Cl. G01R 1/067; G01K 3/00; G01R 31/28; H01L 21/67

(52) U.S. Cl. CPC G01R 1/067; G01K 3/005; G01R 31/2831; H01L 21/67288

(57) ABSTRACT

A prober includes a wafer chuck that is a support member for supporting a wafer, a test part that tests electrical characteristics of semiconductor devices formed on a wafer when the wafer is placed on the wafer chuck, a jetting part that sends air to an air purge line connected to a chuck space formed in the wafer chuck, and a cooling control part that determines whether or not to cause the air to jet out.

### CROSS REFERENCE TO RELATED APPLICATION

This application claims priority from Japanese Patent Application No. 2024-048922, filed on Mar. 26, 2024 in the Japan Patent Office, the contents of which being incorporated by reference herein in its entirety.

### BACKGROUND

The present invention relates to a technology for removing heat from wafers.

A wafer on which a number of devices are formed through front-end processes of semiconductor manufacturing is divided into multiple chips of individual devices in a dicing process. Prior to the dicing process, it is necessary to remove defective devices from the devices on the wafer. Equipment for testing the electrical characteristics of devices formed on each wafer is a prober.

A prober includes a probe card of a plurality of probes. The probes are brought in electrical contact with a test head. A wafer is brought into contact with the probe card, so that the probes touch electrode pads of the devices. Electrical current is applied from the test head to the devices via the probes to test the electrical characteristics so as to determine whether or not each device is a defective device.

As wafers are becoming larger in size and more highly integrated in recent years, the number of devices formed on one wafer is also increasing. There have therefore been demands for increasing throughput in semiconductor manufacturing and improving the efficiency of testing to reduce costs. In this regard, a so-called multi-state prober in which a plurality of stages of multiple measurement parts arranged horizontally are provided in the up-down direction has been proposed. Such a prober can perform testing with a plurality of test heads simultaneously and continuously, which improves the efficiency of testing.
Patent Literature 1: JP H02-065253 A

The testing of the electrical characteristics of wafers (hereinafter simply referred to as a “wafer test”) is performed in view of actual use environments in order to ensure the functionalities of devices, and is therefore performed at high set temperatures of about 85° C. depending on the specifications of the devices.

Electric current flows in the devices during a wafer test, and therefore the devices themselves generate heat. In particular, devices in recent years tend to generate more and more heat. The temperatures of the devices during the wafer test may therefore be higher than set temperatures. In order to maintain set temperatures in a wafer test in a high-temperature environment, excess heat therefore needs to be removed from the devices.

Heat removal using fans or coolants may be considered. In view of saving costs and spaces, however, additional heat removal equipment having a large size is not preferable. In particular, it is also necessary to consider the possibility that coolants may boil in a high-temperature environment. Furthermore, according to verification conducted by the present inventors, “the locality of heat distribution” in which the temperature at a peripheral portion of a wafer lowers relatively quickly while heat tends to accumulate at a central portion of the wafer is found. The inventors have reached an idea that not only heat removal of the whole wafer but also local heat removal targeting at a high-temperature portion of a wafer is also needed.

### SUMMARY

The present invention has been achieved on the basis of recognition of the aforementioned problems by the inventors, and one chief object thereof is to provide a technology for efficiently remove heat from wafers.

A prober according to an aspect includes: a support member that supports a wafer and includes a first flow path through which a first gas passes and a second flow path merging with the first flow path; a test part that tests electrical characteristics of semiconductor devices formed on the wafer when the wafer is placed on the support member; a jetting part that causes a second gas to jet out toward the second flow path; and a cooling control part that instructs the jetting part to or not to cause the second gas to jet out.

A prober according to another aspect includes: a support member that supports a wafer and includes a first flow path through which a first gas passes and a second flow path merging with the first flow path; a test part that tests electrical characteristics of semiconductor devices formed on the wafer when the wafer is placed on the support member; a suction part that sucks the first gas from the second flow path; and a cooling control part that instructs the suction part to or not to suck the first gas.

A wafer cooling method according to an aspect is performed in a prober that includes a support member for supporting a wafer, and tests electrical characteristics of semiconductor devices formed on the wafer.

The support member includes a first flow path through which a first gas passes and a second flow path merging with the first flow path.

The method includes: a step of determining whether or not to cause a second gas to jet out toward the second flow path on the basis of a temperature of the wafer; and a step of causing the second gas to jet out toward the second flow path when jetting of the second gas is permitted.

### BRIEF DESCRIPTION OF DRAWINGS

FIG. 1 is a diagram illustrating a schematic configuration of a prober according to an embodiment;

FIG. 2 is a horizontal sectional view schematically illustrating an internal structure of the prober;

FIG. 3 is a cross-sectional view taken along arrows A-A in FIG. 2;

FIG. 4 is an enlarged diagram of part B in FIG. 3;

FIG. 5 is a diagram illustrating a configuration of a measurement part;

FIG. 6 is a side view of a wafer chuck according to the embodiment;

FIG. 7 is a conceptual diagram of heat distribution of a wafer W;

FIG. 8 is a conceptual diagram for explaining a heat removal method according to the embodiment;

FIG. 9 is a cross-sectional view of a wafer chuck according to the embodiment;

FIG. 10 is an enlarged view of a structure around discharge holes in FIG. 9;

FIG. 11 is a schematic diagram illustrating installation positions of temperature sensors;

FIG. 12 is a system configuration diagram relating to temperature control of the wafer chuck;

FIG. 13 is a flowchart illustrating processes of control of sending air;

FIG. 14 is a cross-sectional view of a wafer chuck according to a first modification;

FIG. 15 is a cross-sectional view of a wafer chuck according to a second modification;

FIG. 16 is a cross-sectional view of a wafer chuck according to a third modification;

FIG. 17 is an external view of a back face of a top plate according to the third modification;

FIG. 18 is an enlarged view of a middle part in FIG. 17;

FIG. 19 is an external view of a surface of a back plate according to a fourth modification;

FIG. 20 is a cross-sectional view of a wafer chuck according to the fourth modification; and

FIG. 21 is a cross-sectional view of a wafer chuck according to a fifth modification.

### DETAILED DESCRIPTION

Some embodiments will now be described. The description is not intended to limit the scope of the invention, but to exemplify the invention.

Hereinafter, an embodiment of the present invention will be described with reference to the drawings. In the following embodiment and modifications thereof, components that are substantially the same will be designated by the same reference numerals and redundant description thereof may be omitted as appropriate.

A prober according to an embodiment tests the electrical characteristics of semiconductor devices (also simply referred to as “devices”) formed on each wafer. The prober includes a plurality of areas including a test area and a conveyance area.

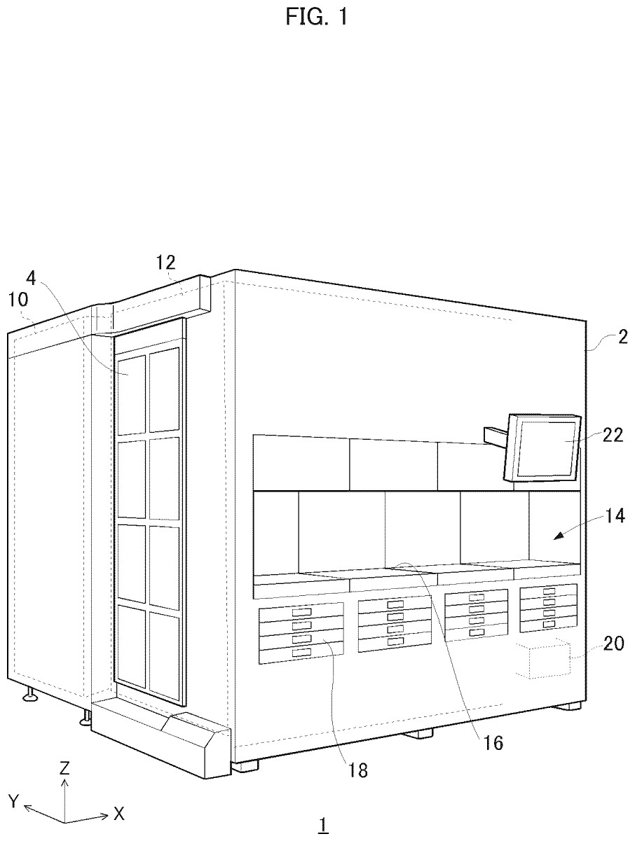

FIG. 1 is a diagram illustrating a schematic configuration of a prober according to an embodiment.

Hereinafter, for convenience of description, the left-right directions, the front-back directions, and the up-down directions when the machine is viewed from the front will be referred to as an X-axis direction, a Y-axis direction, and a Z-axis direction, respectively.

The prober 1 has a housing 2 having a rectangular shape in front view and in plan view. In the housing 2, a measurement area 10 in which wafer tests are performed, and a loader area 12 through which wafers and the like are conveyed into and from the measurement area 10 are located. The loader area 12 includes an accommodating area 14 in which wafers and probe cards are accommodated.

The accommodating area 14 includes a wafer storage part 16 for accommodating wafers and a card storage part 18 for accommodating probe cards. The wafer storage part 16 accepts front opening unified pods (FOUPs) that accommodate a plurality of wafers. A worker or a robot can reach wafers or probe cards to be collected from the front side of the respective storages. A loader door 4 through which the worker goes into and out of the loader area 12 is provided on a side face of the housing 2.

The prober 1 is also provided with a controller 20 and an operation panel 22. The controller 20 is constituted by a general-purpose computer including a CPU for executing various computation processes, a memory or a storage for storing control programs and the like, a memory to be used as a work area for data storage and program execution, an input/output interface, a user interface, and the like. The user interface receives operations input through the operation panel 22 by an operator. The controller 20 controls respective functional units (mechanisms and devices) of the prober 1 in accordance with control programs.

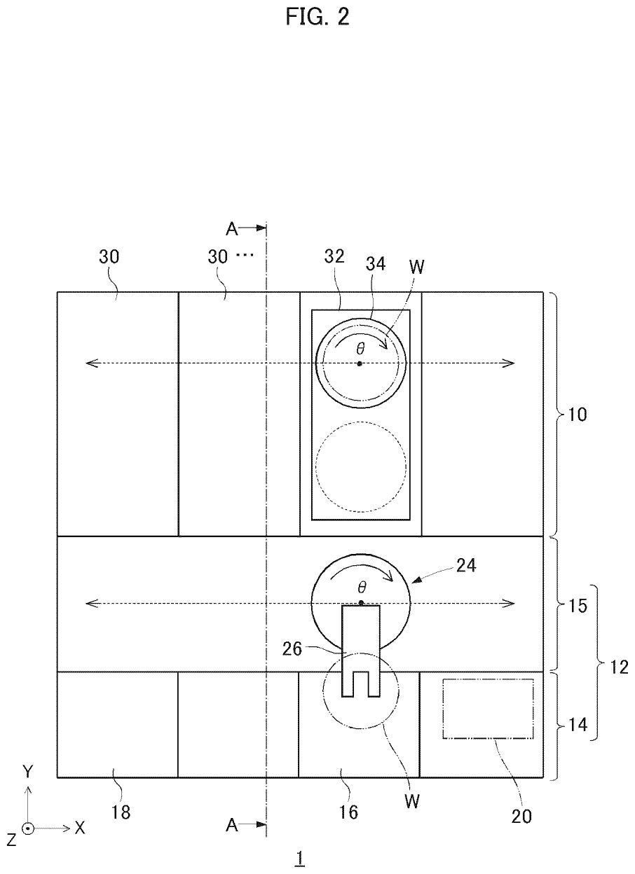

FIG. 2 is a horizontal sectional view schematically illustrating an internal structure of the prober 1.

The prober 1 includes the measurement area 10 and the loader area 12. The measurement area 10 includes the test area, which will be described later. The measurement area 10 and the loader area 12 are partitioned with a partition wall inside the housing 2. The loader area 12 includes the accommodating area 14 and a conveyance area 15. In the conveyance area 15, a conveyance unit 24 for conveying wafers W and probe cards (to be described later) is movably arranged.

In the measurement area 10, a plurality of measurement parts 30 for performing wafer tests are installed. In the embodiment, a multi-stage prober in which three stages of four measurement parts 30 arranged horizontally are provided in the up-down direction is adopted. The number of horizontally arranged measurement parts 30 and the number of stages can be set as appropriate.

In the measurement area 10, an alignment system 32 shared by the measurement parts 30 on all the stages. The alignment system 32 detachably supports wafer chucks 34. Each wafer chuck 34 fixes a wafer W by sucking the wafer W with vacuum suction, and is attached to and detached from a test head of a measurement part 30 in a probing process (details of which will be described later). The alignment system 32 can move among the measurement parts 30 arranged horizontally. Each wafer chuck 34 is movable in X, Y, and Z directions within the measurement area 10 by the operation of the alignment system 32 and is rotatable about an axis in the Z direction (in a direction θ).

The conveyance unit 24 conveys each wafer W between the wafer storage part 16 and each measurement part 30, and conveys each probe card between the card storage part 18 and each measurement part 30. The conveyance unit 24 has an arm 26 for passing each wafer W. The conveyance unit 24 is a conveyor shared by the measurement parts 30 on all the stages, being movable in the X direction and in the Z direction by the operation of a drive mechanism, which is not illustrated, and being rotatable about an axis in the Z direction (in the direction θ).

The conveyance unit 24 advances and retracts (extends and contracts) the arm 26 forward and backward by the operation of an arm driving mechanism, which is not illustrated. A wafer W in the wafer storage part 16 is taken out by the arm 26, and conveyed to a measurement part 30 by the conveyance unit 24. Furthermore, a wafer W after being tested is brought back to the wafer storage part 16 through a reversed path from a measurement part 30.

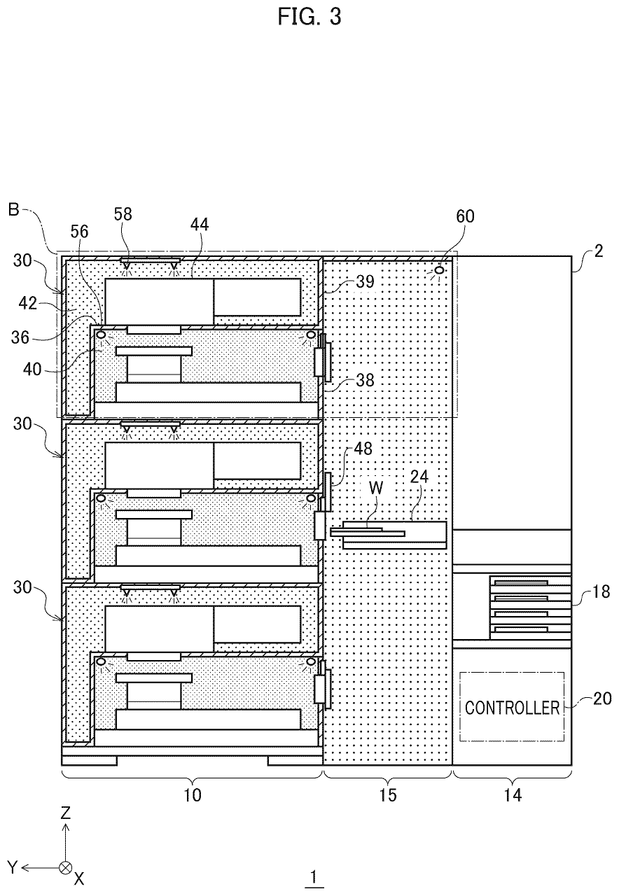

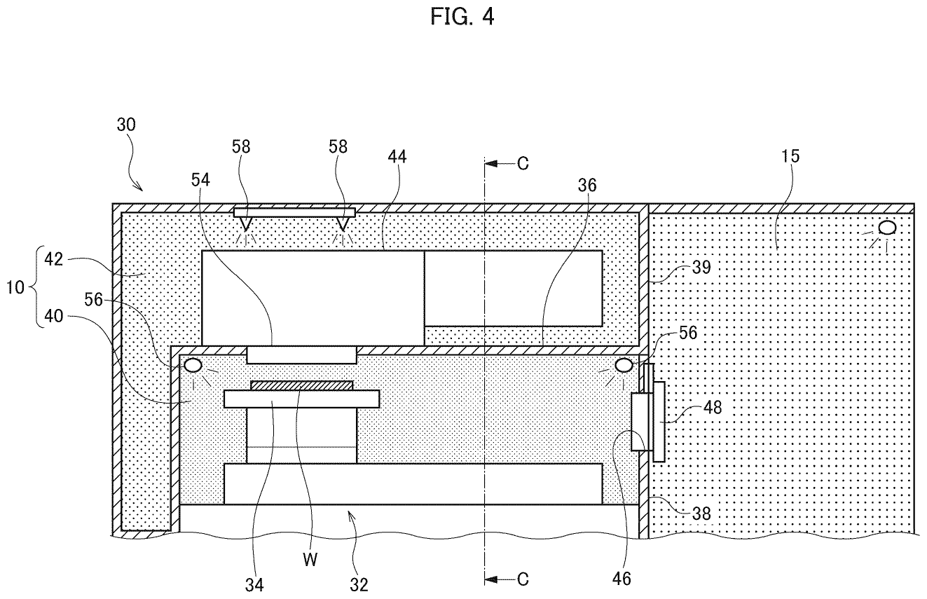

FIG. 3 is a cross-sectional view taken along arrows A-A in FIG. 2. FIG. 4 is an enlarged diagram of part B in FIG. 3.

As illustrated in FIG. 3, three stages of measurement parts s 30 are provided in the up-down direction in the measurement area 10. Each measurement part 30 is defined by a partition 36 in a test area 40 and an equipment accommodating area 42. The test area 40 is an area in which a wafer W to be tested is placed, and is located at a relatively lower position. The equipment accommodating area 42 is an area in which a test head 44 and other electrical equipment are accommodated, and is located at a relatively higher position. The test area 40 is separated from the conveyance area 15 by a partition 38, and the equipment accommodating area 42 is separated from the conveyance area 15 by a partition 39. The equipment accommodating area 42 and the conveyance area 15 correspond to an “outer area” defined separately from the test area 40.

More specifically, as illustrated in FIG. 4, the alignment system 32 is located in the test area 40. The partition 38 has an opening 46 through which the test area 40 and the conveyance area 15 communicate, and a shutter 48 for opening and closing the opening 46. When the shutter 48 is open, the arm 26 of the conveyance unit 24 can be advanced into the test area 40. That is, the wafer W can be passed between the conveyance unit 24 and the alignment system 32.

In the equipment accommodating area 42, the test head 44 and electrical equipment, which is not illustrated, are located. At a boundary between the test area 40 and the equipment accommodating area 42, a pogo frame 54 is arranged. The pogo frame 54 functions as an interface connecting the test head 44 with the probe card (to be described later).

In each area, a discharge part for discharging dry air for preventing dew condensation is provided. A discharge part 56 is provided in the test area 40, and a discharge part 58 is provided in the equipment accommodating area 42. A discharge part 60 is also provided in the conveyance area 15.

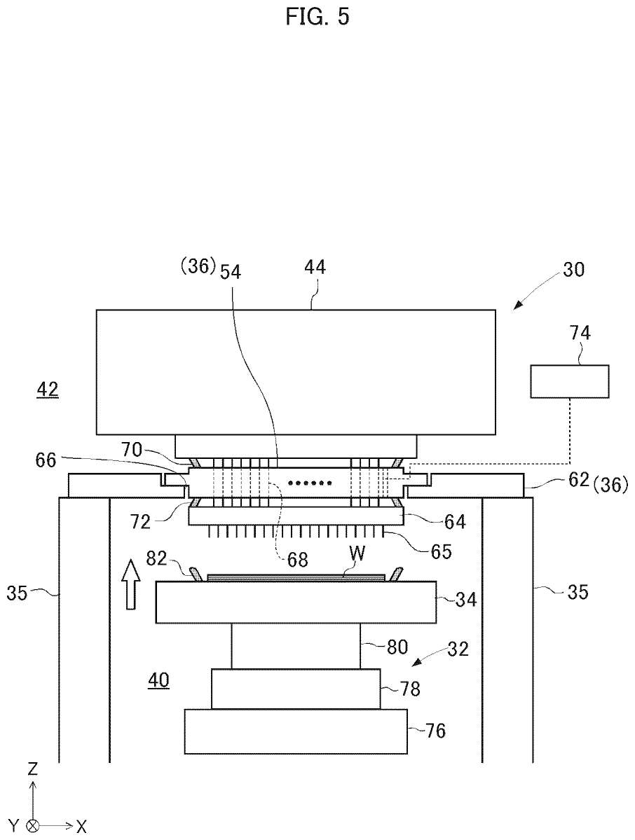

FIG. 5 is a diagram illustrating a configuration of a measurement part 30, and corresponding to a cross section along arrows C-C in FIG. 4.

As illustrated in FIG. 5, each measurement part 30 includes a wafer chuck 34, a test head 44, a pogo frame 54, a head stage 62, and a probe card 64. The probe card 64 includes a number of probes 65 for supplying power to a wafer W.

The pogo frame 54 and the head stage 62 constitute part of the partition 36. The head stage 62 has, at its center, a mounting hole 66 having a complementary shape (circular shape) for mounting the pogo frame 54. The pogo frame 54 is mounted to be fitted into the mounting hole 66, thus closing the mounting hole 66. The head stage 62 has a suction surface capable of sucking the pogo frame 54, and fixes the pogo frame 54 by sucking the pogo frame 54 with a suction device (a vacuum pump, for example), which is not illustrated. The boundary between the head stage 62 and the pogo frame 54 is kept airtight. In a modification, however, the head stage 62 and the pogo frame 54 may be fixed by a fixing structure such as screws.

The test head 44 is supported above the head stage 62. The test head 44 is electrically connected with the probes 65 of the probe card 64, supplies test signals (electrical signals) to respective devices on the wafer W during testing, and detects signals output from the respective devices to obtain electrical characteristics thereof. In this manner, whether the respective devices work properly is tested.

The pogo frame 54 has a number of pogo pins 68 for electrically connecting terminals formed on a lower face (a face facing the pogo frame 54) of the test head 44 with terminals formed on an upper face of (a face facing the pogo frame 54) of the probe card 64. In addition, seal rings 70 and 72 are arranged on peripheral edges of an upper face (a face facing the test head 44) and a lower face (a face facing the probe card 64), respectively, of the pogo frame 54.

When a suction device 74 (a vacuum pump, for example) is activated, a space surrounded by the test head 44, the pogo frame 54, and the seal ring 70 and a space surrounded by the probe card 64, the pogo frame 54, and the seal ring 72 are reduced in pressure. As a result, the test head 44, the pogo frame 54, and the probe card 64 are integrated.

According to this configuration, an inner space (that is, the test area 40) and an outer space (that is, the equipment accommodating area 42) are separated from each other by the partition 36 including the head stage 62 and the pogo frame 54. Note that, in the embodiment, even when the probe card 64 is removed from the pogo frame 54 for replacement of the probe card 64, the function of the seal ring 70 maintains the airtightness between the test area 40 and the equipment accommodating area 42.

The probe card 64 has a plurality of probes 65 for electrodes of the respective devices on the wafer W to be tested. When the test head 44, the pogo frame 54, and the probe card 64 are integrated as described above, the probes 65 are electrically connected with the terminals of the test head 44 via the pogo frame 54. The probe card 64 includes a number of probes 65 for the electrodes of all the devices on the wafer W to be tested, and all the devices on the wafer W are simultaneously tested in the measurement part 30.

The wafer chuck 34 sucks to fix the wafer W. The wafer chuck 34 is detachably supported by the alignment system 32. The alignment system 32 includes an X table 76, a Y table 78, and a Z table 80.

A guide rail extending in the X direction is provided in the housing 2, and the X table 76 is horizontally arranged to be movable in the X direction along the guide rail. The X table 76 is driven by a moving mechanism, which is not illustrated. A guide rail extending in the Y direction is provided on an upper face of the X table 76. The Y table 78 is horizontally arranged to be movable in the Y direction along the guide rail. The Y table 78 is driven by a moving mechanism, which is not illustrated. Each moving mechanism may be constituted by a feed screw mechanism and a servomotor that drives the feed screw mechanism, or may be constituted by a linear motor.

The Z table 80 is supported to be movable, up and down, in the Z direction and rotatable in the direction θ by the Y table 78. The Y table 78 is provided with a lifting mechanism for moving the Z table 80 up and down and a rotating mechanism for rotating the Z table 80 (which are not illustrated). The rotating mechanism is constituted by a spindle motor, for example. The wafer chuck 34 is detachably supported by an upper face of the Z table 80. This configuration allows the wafer chuck 34 to be moved in each of the X direction, the Y direction, the Z direction, and the direction θ. Movement of the wafer chuck 34 enables the wafer W to be positioned relative to the probe card 64.

Chuck sealing rubber 82 (a seal ring) is arranged to surround the wafer W on the upper face of the wafer chuck 34. In the probing process, the Z table 80 is moved to move the wafer chuck 34 (up and down) toward the probe card 64. At this point, the chuck sealing rubber 82 comes in contact with the lower face of the probe card 64, and a space surrounded by the wafer chuck 34, the probe card 64, and the chuck sealing rubber 82 is thus formed. A suction device (a vacuum pump, for example), which is not illustrated, is activated to reduce the pressure in the space, and the wafer chuck 34 is therefore pulled toward the probe card 64. As a result, the probes 65 of the probe card 64 come into contact with the respective devices on the wafer W, and a wafer test can be conducted.

At this point, the Z table 80 can be separated from the wafer chuck 34, so that the alignment system 32 can be used for another measurement part 30. As described above, the alignment system 32 is shared by the measurement parts 30 on all the stages, a wafer W can be passed in a measurement part 30 while testing g is being performed in another measurement part 30.

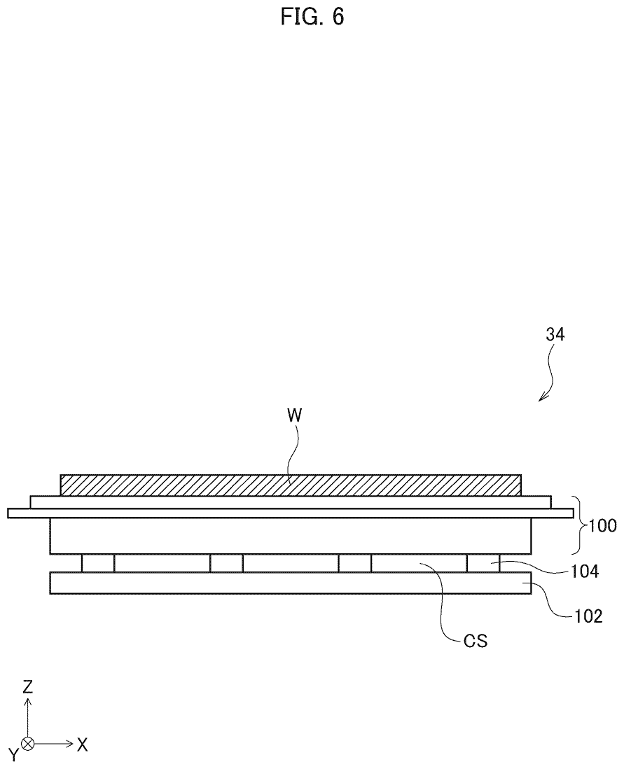

FIG. 6 is a side view of the wafer chuck 34 according to the embodiment.

The wafer chuck 34 is a disk-shaped “support member” on which a wafer W is placed. The wafer chuck 34 includes a top plate 100 and a back plate 102. The top plate 100 (a chuck top) also needs to function as a measuring electrode in a wafer test, and is therefore made of a conducting material such as metal. The top plate 100 includes a heater for heating a wafer W, which will be described later.

The back plate 102 is made of a highly insulating material such as ceramics to prevent leakage current during a wafer test. The top plate 100 and the back plate 102 are connected with each other via a plurality of spacers 104 by screws. The spacers 104 form a gap (hereinafter referred to as a “chuck space CS”) between the top plate 100 and the back plate 102. The heat of the wafer W and the heater increase the temperature of the top plate 100, which also increases the temperature of the air in the chuck space CS (hereinafter, the heated air will be referred to as “hot air”). As dry air at ordinary or low temperatures (hereinafter simply referred to as “air”) flows through the chuck space CS, the hot air is removed.

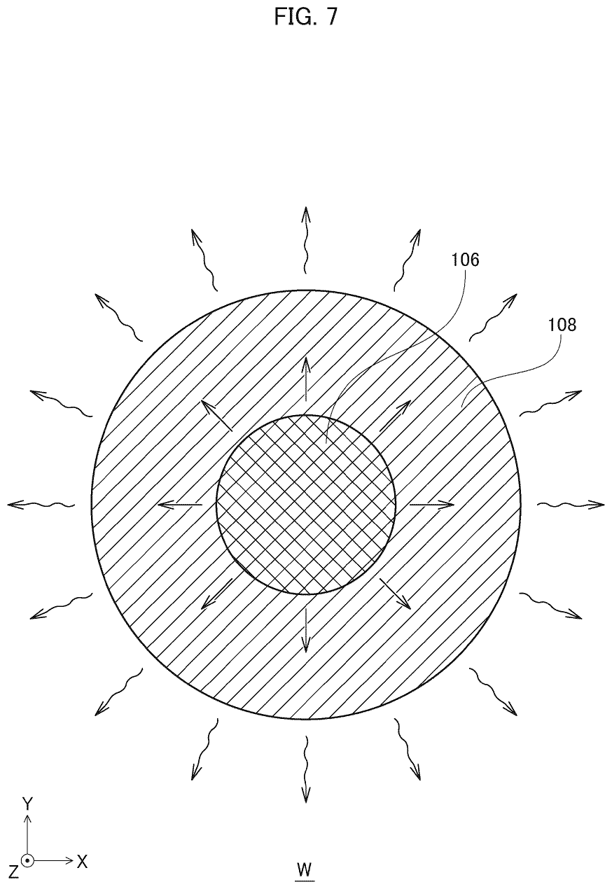

FIG. 7 is a conceptual diagram of heat distribution of a wafer W.

During a wafer test, the whole wafer W is heated by a heater. In addition, devices formed on the wafer W also produce heat as electrical current is applied to the devices during the wafer test. In a wafer test in a high temperature environment (hereinafter simply referred to as a “high temperature test”), the devices also produce heat. In a high temperature test, a set temperature needs to be maintained in view of the heat produced by the devices.

In a high temperature test, heat from the wafer W and the wafer chuck 34 is lost little by little from a peripheral portion to the outside air. Thus, the temperature at a peripheral portion 108 of the wafer W lowers relatively easily. In contrast, heat at the central portion 106 of the wafer W is conducted to the peripheral portion 108 and then lost to the outside air. The temperature at the central portion 106 is therefore less likely to lower than at the peripheral portion 108. Thus, in a high temperature test, when the heating value of the wafer W is large, the temperature at the central portion 106 may reach a set temperature or higher. In order to keep the temperature of the whole wafer W around the set temperature (measurement temperature), it is particularly necessary to promote heat removal from the central portion 106.

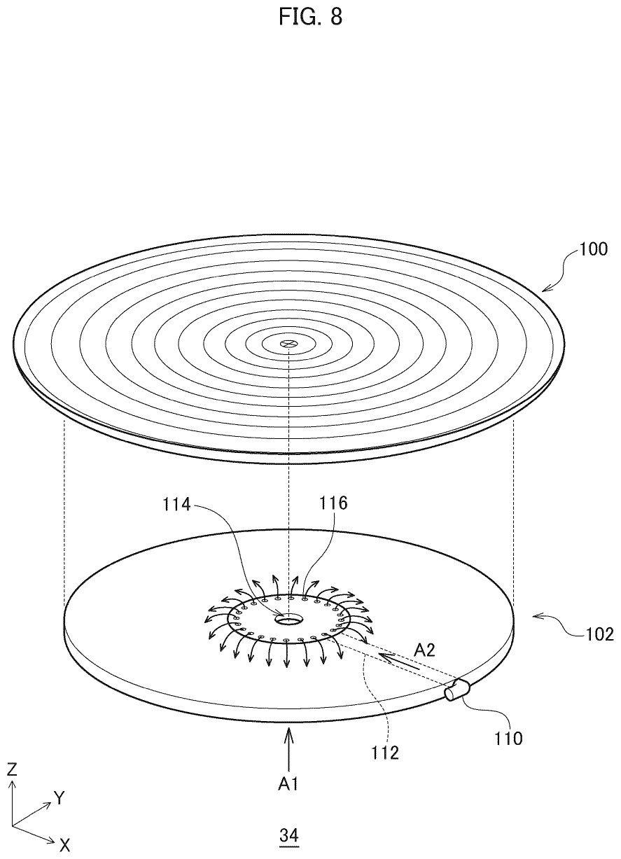

FIG. 8 is a conceptual diagram for explaining a heat removal method according to the embodiment.

An air hole 114 is formed at the center of the back plate 102. Air A1 (first gas) flows from the lower face of the back plate 102 through the air hole 114 and into the chuck space CS. The air A1 is radially dispersed in the chuck space CS, and exits from the peripheral portion of the wafer chuck 34 (first flow path). The air A1 may be actively blown from below the back plate 102 by a fan or the like, but the air A1 according to the embodiment is made to slowly flow into the test area 40 by dry air supply.

In the embodiment, air A2, which is “second gas”, is further let into an air purge introducing part 110 provided on a side face of the back plate 102. The air A2 is compressed air. The air A2 being let in through the air purge introducing part 110 is led to the middle of the back plate 102 through an air purge line 112 formed inside the back plate 102, and jets out from a number of discharge holes 116 formed around the air hole 114 into the chuck space CS (second flow path). The air A2 jets out at a high flow rate, which causes a negative pressure.

When the air A2 jets out from the discharge holes 116 arranged radially, the air A1 is drawn by the negative pressure of the air A2, which promotes removal of hot air, that is, removal of heat from the wafer W. Because the discharge holes 116 are arranged right below the central portion 106 of the wafer W, the synergy of the air A1 and the air A2 particularly increases the effect of heat removal from the central portion 106. Note that, as described above, a fan, which is not illustrated, may assist the entry of the air A1 from the lower face of the back plate 102.

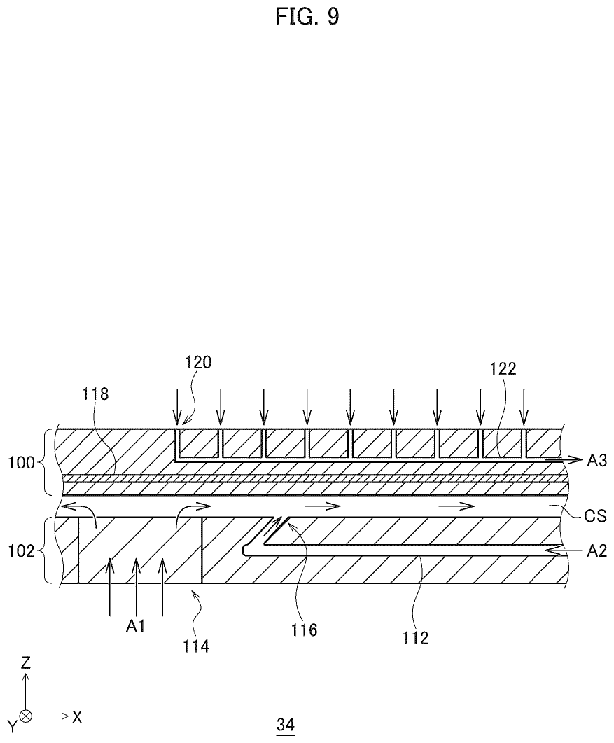

FIG. 9 is a cross-sectional view of the wafer chuck 34 according to the embodiment.

The top plate 100 includes a heater 118 for heating the wafer W. A suction tube 122 is formed above the heater 118. A number of suction holes 120, which communicate with the suction tube 122, are formed on the surface of the top plate 100. A suction part, which will be described later, sucks air A3 from the suction tube 122. The wafer W is sucked onto the top plate 100 by the suction from the suction holes 120.

The air A1 flows from the air hole 114 of the back plate 102 toward the back face of the top plate 100. The flow rate of the air A1 is higher through the air hole 114 than through the air purge line 112. The air A2, together with the air A1, pushes hot air in the chuck space CS out toward the periphery (the X-axis direction in FIG. 9) of the wafer chuck 34.

The air purge line 112 described above is formed inside the back plate 102. The high-pressure air A2 supplied from the air purge introducing part 110 into the air purge line 112 jets out into the chuck space CS through the discharge holes 116. The air A2 is supplied when a temperature condition, which will be described later, is satisfied and, together with the air A1, removes the hot air.

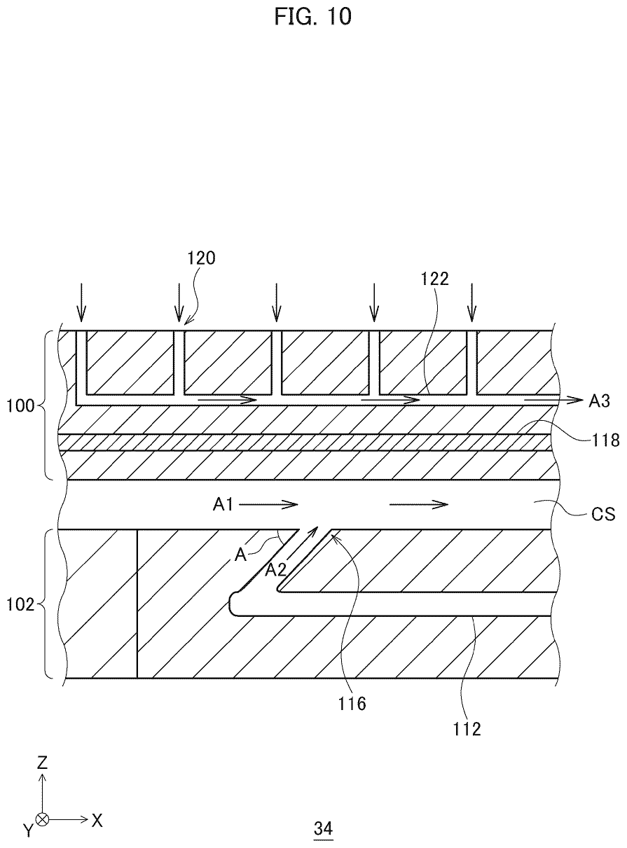

FIG. 10 is an enlarged view of a structure around the discharge holes 116 in FIG. 9.

The air A2 jetting out from the discharge holes 116 merges with the air A1 flowing through the chuck space CS. The air purge line 112 is designed so that a merging angle A between the moving direction of the air A1 and the moving direction of the air A2 is an acute angle. The merging angle A is an acute angle so that the moving directions of the air A1 and the air A2 get aligned. The air A1 is therefore smoothly drawn by the negative pressure caused by the air A2 when the air A2 jets out from the discharge holes 116. As a result of the effect of accelerating the flow of the air A1 by the air A2, hot air stagnating in the chuck space CS is strongly pushed out. The air A2 is lower in volume and higher in pressure than the air A1, and is caused to flow intermittently. When the air A2 jets out, the hot air, which tends to accumulate at the center of the top plate 100, is strongly removed.

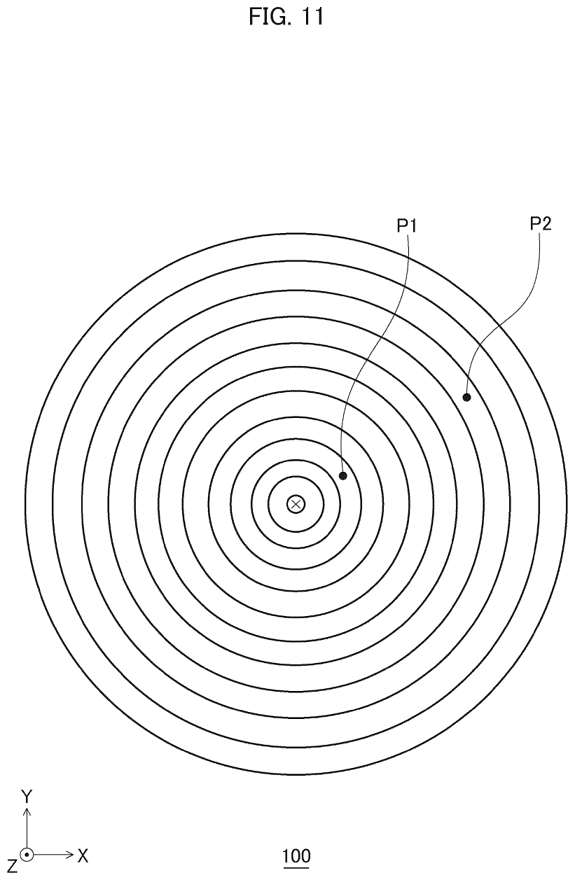

FIG. 11 is a schematic diagram illustrating installation positions of temperature sensors.

Two temperature sensors are installed, one at a point P1 (first position) closer to the center of the top plate 100 and the other at a point P2 (second position) closer to the outer edge thereof. The temperature sensors may be known sensors such as a resistance thermometer or a thermocouple. Hereinafter, the temperature measured at the point P1 will be referred to as a “central temperature (first temperature)”, and the temperature measured at the point P2 will be referred to as a “peripheral temperature (second temperature)”.

The air A2 is supplied to the air purge introducing part 110 when either of the following two temperature conditions is satisfied.

central temperature+peripheral temperature>threshold T1 (first threshold) temperature condition 1:

central temperature>peripheral temperature+threshold T2 (second threshold) temperature condition 2:

The first threshold and the second threshold may be freely set by a user. For example, the threshold T1 may be “(set temperature+1)*2 [° C.]”, and the threshold T2 may be “1 [° C.]”. The set temperature may be any degrees, and may be set as a temperature in a high temperature test such as at 100 [° C.], for example.

With regard to the temperature condition 1, if the set temperature is 100 [° C.], the central temperature is 103 [° C.], and the peripheral temperature is 100 [° C.], for example, the threshold T1 is (100+1)*2=202 [° C.]. In this case, “(the central temperature)+ (the peripheral temperature)=203 [° C.]” is obtained, the temperature condition 1 is therefore satisfied, and the air A2 is caused to jet out.

The temperature condition 1 indicates a state in which the temperature of the wafer W as a whole is increased. The temperature condition 2 indicates a state in which heat remains at the central portion 106 of the wafer W.

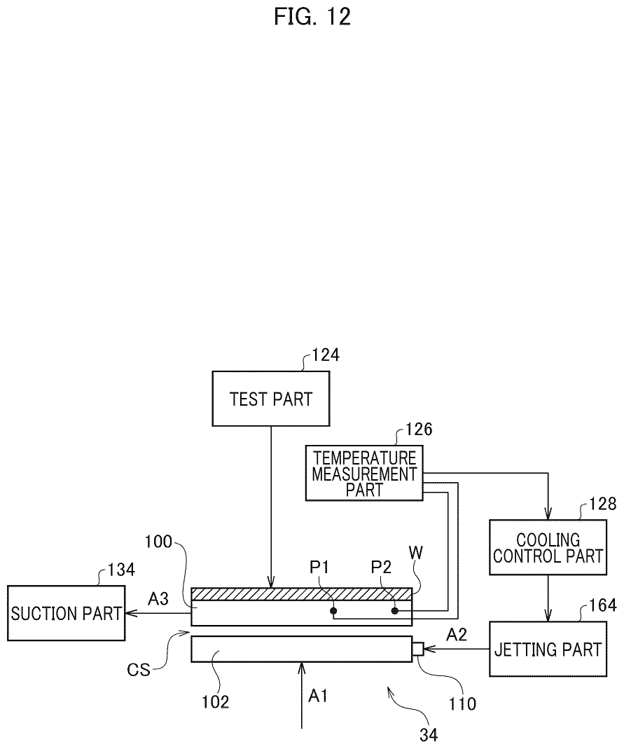

FIG. 12 is a system configuration diagram relating to temperature control of the wafer chuck 34.

A test part 124 performs a wafer test on a wafer W placed on the top plate 100. Specifically, the test part 124 corresponds to the test head 44, the pogo frame 54, the pogo pins 68, the probe card 64, the probes 65, and the controller 20 that controls these components.

A suction part 134 sucks the air A3 from the suction tube 122 in the top plate 100. A jetting part 164 sends the air A2 from the air purge introducing part 110 of the back plate 102. A temperature measurement part 126 measures the central temperature and the peripheral temperature. A cooling control part 128 determines whether or not a temperature condition is satisfied on the basis of the two temperatures measured by the temperature measurement part 126. The cooling control part 128 is part of the controller 20. When either one of the two temperature conditions is satisfied, the cooling control part 128 instructs the jetting part 164 to cause the air A2 to jet out.

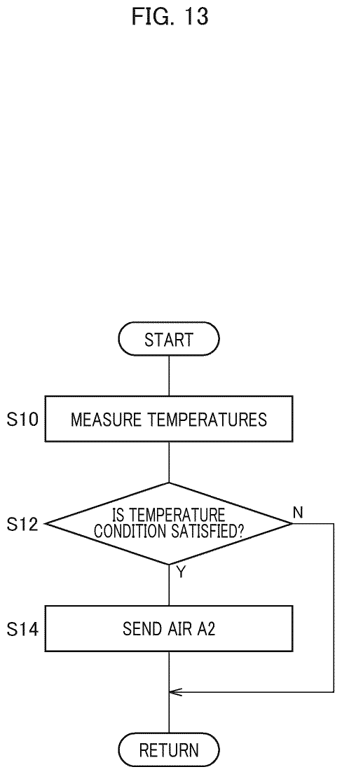

FIG. 13 is a flowchart illustrating processes of control of sending the air A2.

The processes illustrated in FIG. 13 are repeated periodically, such as every one minute, in a high temperature test by the cooling control part 128. As described above, the air A1 constantly supplied. The temperature measurement part 126 measures the central temperature and the peripheral temperature (S10). The cooling control part 128 determines whether either of the two temperature conditions is satisfied (S12). If neither of the temperature conditions is satisfied (N in S12), subsequent processes are skipped. If either of the temperature conditions is satisfied (Y in S12), the cooling control part 128 instructs the jetting part 164 to cause the air A2 to jet out, and the jetting part 164 causes the air A2 to jet out from the air purge introducing part 110 (S14).

The prober 1 has been described above mainly on a temperature control system of the wafer chuck 34 on the basis of the embodiment.

The air A2 is caused to jet out along the flow of the air A1, which increases the flowability of the air A1. Active removal of hot air from the rear side of the top plate 100 facilitates decrease in the temperature of the wafer W. In particular, the discharge holes 116 formed radially at the central portion of the back plate 102 allow efficient heat removal from the central portion 106 of the wafer W.

When the temperature of the whole wafer W is high (temperature condition 1) or when the temperature of the wafer W is higher at the central portion 106 than the peripheral portion 108 (temperature condition 2), the cooling control part 128 instructs jetting of the air A2. Because the air A2 does not constantly jet out but is caused to jet out only when the necessity of heat removal is high, power consumption associated with control of the air A2 can be suppressed to the minimum necessary. The jetting part 164 may generate the high-pressure air A2 by compressing part of the dry air supplied to the test area 40. Because little additional equipment for the air A2 is needed, an increase in the size of equipment can be prevented.

The air A2 itself removes the hot air, but a chief purpose thereof is to promote the flowability of the air A1. Because the air A2 causes a negative pressure near the discharge holes 116, the air A1 and the air A2 come together, which facilitates removal of the hot air.

The present invention is not limited to the embodiments described above and modifications thereof, and any component thereof may be modified and embodied without departing from the scope of the invention. Components described in the embodiments and modifications may be combined as appropriate to form various embodiments. Some components may be omitted from the components presented in the embodiments and modifications.

### MODIFICATIONS

In the embodiment, the air A1 has been described as being generated as a natural flow of dry air supplied to the test area 40. In a modification, an “air blower” such as a fan may be installed below the air hole 114, and the air A1 may be actively supplied by the air blower.

The air A1 and the air A2 in the embodiment have been described as being air. The air A1 and the air A2 may be gas other than air, such as hydrogen gas or nitrogen gas.

The jetting part 164 may supply the air A2 on the basis of a condition other than the temperature conditions. For example, the jetting part 164 may continuously supply the air A2 for a predetermined time during a high temperature test, such as for 10 seconds before a high temperature test is terminated. Alternatively, the temperature measurement part 126 may inform a user of the temperature distribution of the wafer W, and the user may instruct the jetting part 164 to cause the air A2 to jet out as necessary by using the operation panel 22.

The cooling control part 128 may cause the air A2 to jet out when the temperature inside the test area 40, instead of the temperature of the wafer W, has reached a predetermined threshold or higher. The temperature conditions may be freely set on the basis of combination of various temperatures such as central temperature/peripheral temperature, (central temperature-peripheral temperature)/peripheral temperature, or {(central temperature+peripheral temperature)/2}−inside temperature. Alternatively, temperature conditions maybe set not only on the basis of the central temperature, the peripheral temperature, and/or the inside temperature but also on the basis of decrease rates pre unit time of these temperatures. For example, a temperature condition may be satisfied when the difference between the decrease rate per second of the peripheral temperature and the decrease rate per second of the central temperature is larger than a predetermined threshold, that is, in other words, when the decrease of the central temperature is significantly delayed as compared with the decrease of the peripheral temperature. Various thresholds relating to temperature conditions may be freely set by the user by using the operation panel 22.

The number of temperature sensors installed on the wafer chuck 34 may be one. For example, a temperature condition may be satisfied when the temperature measured by the only temperature sensor has reached a predetermined threshold or higher. The number of temperature sensors may be three or more. The user may set a temperature condition on the basis of combination of a plurality of temperatures (measurement values).

Hereinafter, first to fifth modifications of the method for controlling the temperature of the wafer chuck 34 will be described.

### First Modification

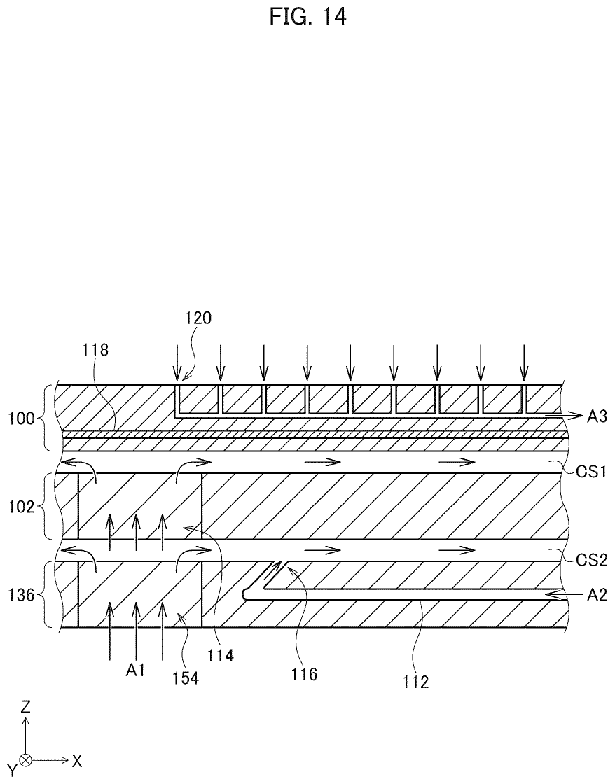

FIG. 14 is a cross-sectional view of a wafer chuck 34 according to a first modification.

In the first modification, a chuck base 136 for supporting the back plate 102 is connected to the lower face of the back plate 102. A chuck space CS1 is formed between the top plate 100 and the back plate 102, and a chuck space CS2 is formed between the back plate 102 and the chuck base 136.

An air hole 154 communicating with the air hole 114 of the back plate 102 is formed at the center of the chuck base 136. The air purge line 112 in the first modification is not formed in the back plate 102 but formed in the chuck base 136. The air A1 flows through both of the chuck space CS1 and the chuck space CS2. The air A2 is caused to jet out from the discharge holes 116 to remove heat from the chuck space CS2. The air purge line 112 can be formed in a structure other than the back plate 102 as in the first modification. The air purge line 112 may be formed in both of the back plate 102 and the chuck base 136.

In the first modification as well, a number of discharge holes 116 are arranged radially around the air hole 154 in the same manner as the illustration in FIG. 8.

### Second Modification

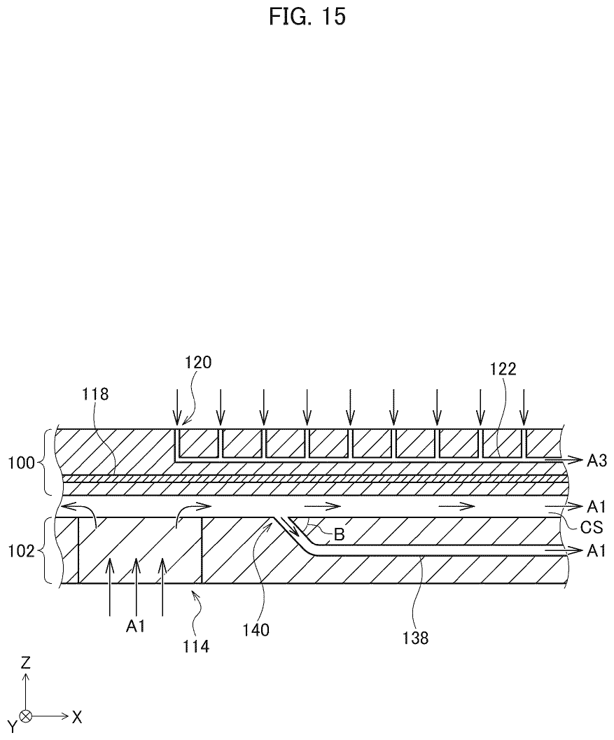

FIG. 15 is a cross-sectional view of a wafer chuck 34 according to a second modification.

In the second modification, the air A1 is partly sucked by a “suction part”, which is not illustrated, through a suction tube 138 formed in the back plate 102. When a temperature condition is satisfied, the cooling control part 128 instructs the suction part to suck the air A1. In this case, the air A1 flowing through the chuck space CS is partly sucked through suction holes 140 into the suction tube 138. The suction tube 138 is arranged so that an angle B between the moving direction of the air A1 flowing through the suction tube 138 and the moving direction of the air A1 flowing through the chuck space CS is an acute angle. The suction of part of the air A1 allows efficient removal of hot air stagnating in the chuck space CS.

In the second modification as well, a number of suction holes 140 are arranged radially around the air hole 114 in the same manner as the illustration in FIG. 8.

### Third Modification

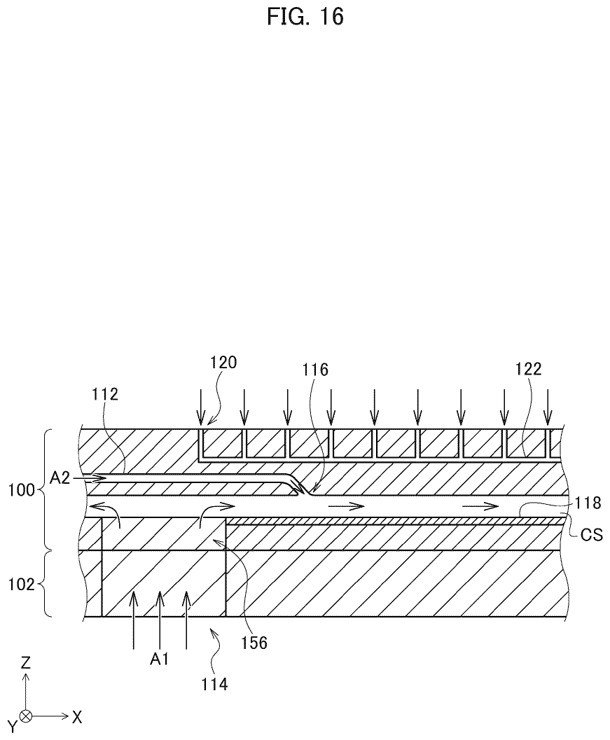

FIG. 16 is a cross-sectional view of a wafer chuck 34 according to a third modification.

In the third modification, the air purge line 112 is not formed in the back plate 102 but formed in the top plate 100. In addition, a chuck space CS is formed in the top plate 100 and above the heater 118. In the third modification, the top plate 100 and the back plate 102 may adhere to each other. A communication hole 156 communicating with the air hole 114 is formed at the center of the top plate 100. The air A1 supplied through the air hole 114 removes hot air in the chuck space CS above the heater 118.

When a temperature condition is satisfied, the cooling control part 128 instructs the jetting part 164 to cause the air A2 to jet out. When the jetting part 164 sends the air A2, the air A2 jets out from the discharge holes 116 above the heater 118, merges with the air A1, and thus accelerates the flow of the air A1.

In the second modification as well, a number of discharge holes 116 are arranged radially around the air hole 114 and the communication hole 156.

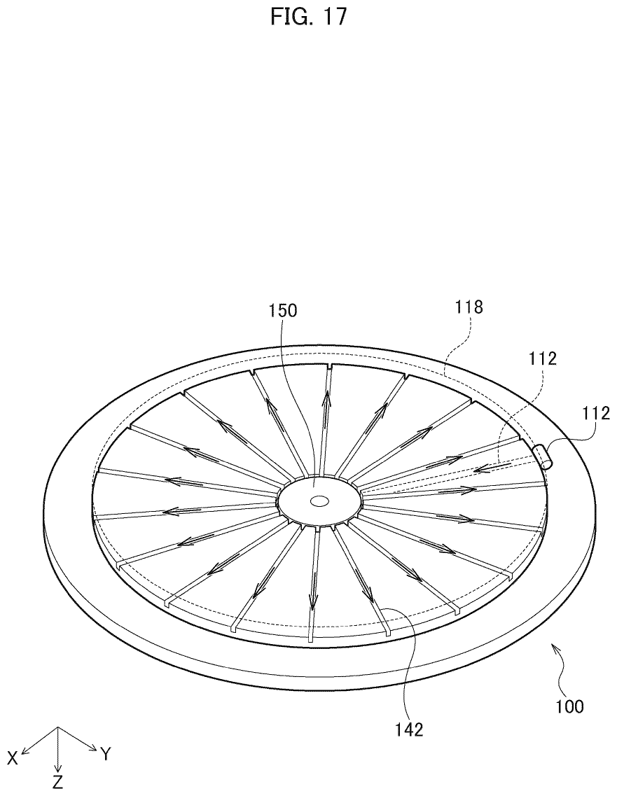

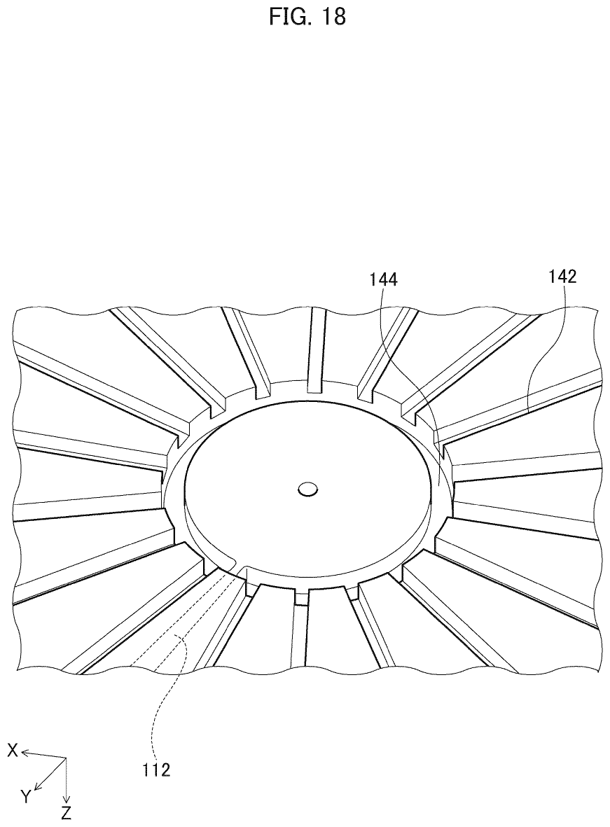

FIG. 17 is an external view of the back face of the top plate 100 according to the third modification. FIG. 18 is an enlarged view of a middle part in FIG. 17.

As described above, the chuck space CS is formed above the heater 118 (on the positive direction side of the Z axis in FIG. 17) in the third modification. In addition, a plurality of radial grooves 142 are formed radially on the back face of the top plate 100. The compressed air A2 supplied from the air purge line 112 is led to a circular groove 144 at the center of the top plate 100. The circular groove 144 is shielded by a cover 150, and the air A2 flowing through the circular groove 144 enters into the radial grooves 142. FIG. 18 illustrates an internal structure of the circular groove 144 in a state in which the cover 150 is removed.

The air A2 flows toward the periphery along the radial grooves 142, which quickly moves out the hot air in the chuck space CS. In the third modification, the chuck space CS is formed above the heater 118, which is a heat source, which further increases the heat removing effect.

### Fourth Modification

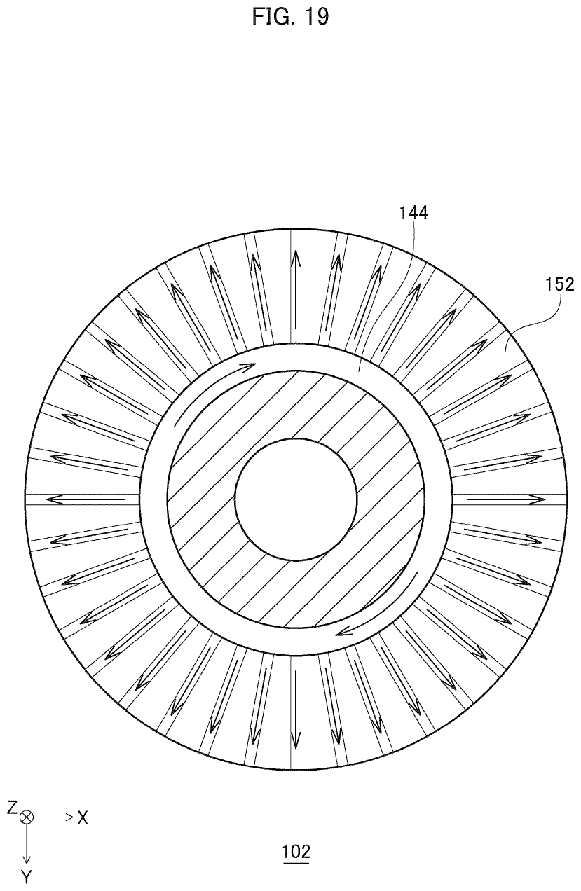

FIG. 19 is an external view of the surface of the back plate 102 according to a fourth modification.

A large circular groove 144 is formed around the air hole 114 of the back plate 102 according to the fourth modification. A number of radial grooves 152 are formed to extend from the circular groove 144. The radial grooves 152 may be slits for guiding the air A2 toward the periphery. In the fourth modification, the air A2 is sent into the circular groove 144, then led to the radial grooves 152, and radially discharged.

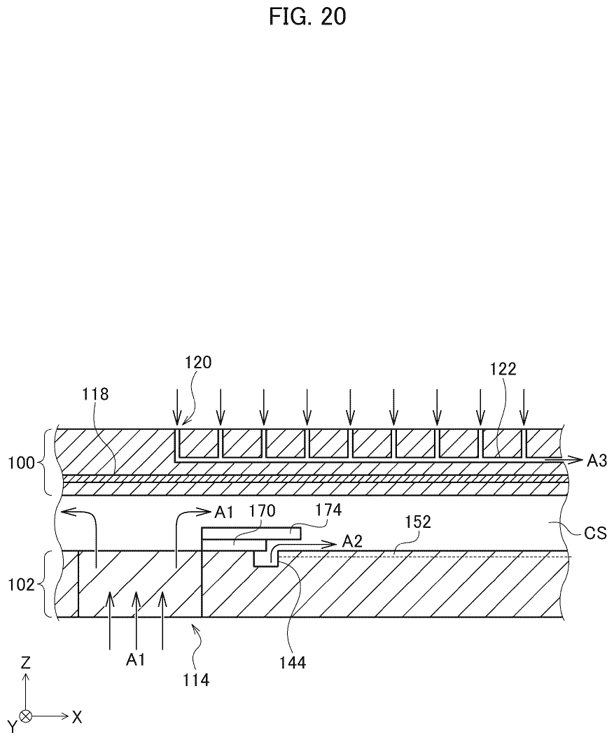

FIG. 20 is a cross-sectional view of a wafer chuck 34 according to the fourth modification.

A first circular plate 170 for partially shielding the circular groove 144 is placed above the circular groove 144. A larger second circular plate 174 for shielding the whole circular groove 144 is further placed above the first circular plate 170. Both of the first circular plate 170 and the second circular plate 174 are annular members centered at the air hole 114.

The first circular plate 170 and the second circular plate 174 function as an “air direction adjusting structure” for guiding the air A2, which is flowing through the circular groove 144, in the radial direction (in the X-axis direction in FIG. 20). The air A2 flowing through the circular groove 144 is caused to jet out from the top of the circular groove 144, and the moving direction of the air A2 is then changed to the radial direction by the first circular plate 170 and the second circular plate 174. As described with reference to FIG. 19, because a number of radial grooves 152 are formed on the side face of the circular groove 144, the air A2 is also guided by the radial grooves 152, in addition to the first circular plate 170 and the second circular plate 174, which accelerate discharge of hot air by the air A1.

### Fifth Modification

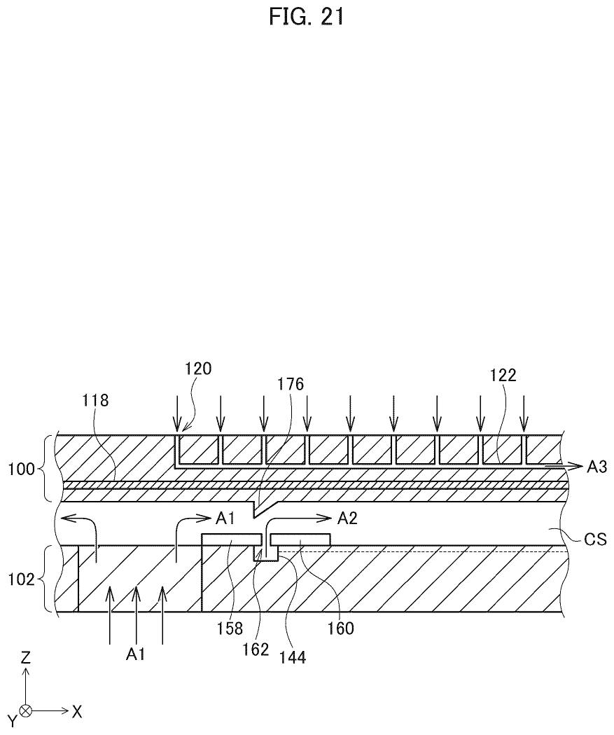

FIG. 21 is a cross-sectional view of a wafer chuck 34 according to a fifth modification.

In the fifth modification as well, as described with reference to FIG. 19, a circular groove 144 is formed on the back face of the back plate 102. Although radial grooves 152 are not necessary on the back plate 102 of the fifth modification, the radial grooves 152 may be formed. A first circular plate 158 and a second circular plate 160 for partially shielding the circular groove 144 are placed above the circular groove 144. Both of the first circular plate 158 and the second circular plate 160 are annular members centered at the air hole 114.

The first circular plate 158 and the second circular plate 160 form a discharge groove 162 above the circular groove 144, and the high-pressure air A2 caused to flow through the circular groove 144 jets out upward (in the positive direction of the Z axis in FIG. 21) from the discharge groove 162. An annular deflecting member 176 is placed on the back face of the top plate 100, the deflecting member 176 being positioned at the top position of the discharge groove 162. The deflecting member 176 functions as an “air direction adjusting structure” for guiding the air A2, which is blowing up from the discharge groove 162, in the radial direction. The air A2 flowing through the circular groove 144 blows up from the discharge groove 162, and then guided in the radial direction by the deflecting member 176, which accelerates discharge of hot air from the chuck space CS.

In the configurations of the fourth modification and the fifth modification, additional members such as the first circular plate 158 is used to adjust the air direction instead of the air purge line 112 formed to bend at an acute angle as illustrated in FIG. 9, etc., which is advantageous in easiness of manufacture.

The air A2 flowing through the circular groove 144 flows into the radial grooves 152 toward the periphery. The flow rates of the air A2 at the entries of all the radial grooves 152 are preferably uniform.

In a modification, the flow rates of the air A2 through the radial grooves 152 may be intentionally made non-uniform. For example, assume that it is known that a wafer W tends to be higher in temperature at a position Q1 that at another position Q2 owing to such reason as individual differences among wafers W or the wafer chucks 34. In this case, the entry of a radial groove 152 near the position Q1 may be made larger so that hot air near the position Q1 is more strongly removed than the hot air near the position Q2. In this manner, the size of the entries of the radial grooves 152, the lengths, the widths, or the like of the radial grooves 152 may be adjusted depending on estimated temperature distribution of the wafer W.

What is claimed is:

1. A prober comprising:
a support member for supporting a wafer, the support member including a first flow path through which a first gas passes and a second flow path merging with the first flow path;
a test part that tests electrical characteristics of semiconductor devices formed on the wafer when the wafer is placed on the support member;
a jetting part that causes a second gas to jet out toward the second flow path; and
a cooling control part that instructs the jetting part to or not to cause the second gas to jet out.

2. The prober according to claim 1, wherein the second flow path merges with the first flow path at an angle.

3. The prober according to claim 1, wherein the second flow path includes a plurality of flow paths for radially sending the second gas from a central portion toward a peripheral portion of the support member.

4. The prober according to claim 1, wherein when a predetermined temperature condition is satisfied, the cooling control part instructs jetting out of the second gas.

5. The prober according to claim 4, further comprising:
a temperature measurement part measures a first temperature being a temperature at a first position of the wafer, and a second temperature being a temperature at a second position of the wafer, the second position being on an outer side of the first position,
wherein the temperature condition is a predetermined relation between the first temperature and the second temperature, and the cooling control part instructs jetting out of the second gas when the temperature condition is satisfied.

6. The prober according to claim 5, wherein the temperature condition is a sum of the first temperature and the second temperature being equal to or larger than a first threshold, and the cooling control part instructs jetting out of the second gas when the temperature condition is satisfied.

7. The prober according to claim 5, wherein the temperature condition is the first temperature being equal to or larger than a sum of the second temperature and a second threshold, and the cooling control part instructs jetting out of the second gas when the temperature condition is satisfied.

8. The prober according to claim 1,
wherein the support member includes a top plate on which the wafer is to be placed, and a back plate that supports the top plate,
wherein the first flow path is a gap between the top plate and the back plate,
wherein the second flow path is formed inside the back plate, and
wherein a merging point of the second flow path with the first flow path is a discharge hole from the back plate toward the top plate.

9. The prober according to claim 8, wherein the top plate or the back plate includes an air direction adjusting structure that guides part of the second gas toward a periphery of the top plate.

10. The prober according to claim 1,
wherein the support member includes a top plate on which the wafer is to be placed, a back plate that supports the top plate, and a chuck base that supports the back plate,
wherein the first flow path is a gap between the back plate and the chuck base,
wherein the second flow path is formed inside the chuck base, and
wherein a merging point of the second flow path with the first flow path is a discharge hole from the chuck base toward the back plate.

11. The prober according to claim 1,
wherein the support member includes a top plate on which the wafer is to be placed, and a back plate that supports the top plate,
wherein the top plate includes a heater,
wherein the first flow path is a gap facing a face of the top plate on which the heater is present,
wherein the second flow path is formed inside the top plate, and
wherein a merging point of the second flow path with the first flow path is a discharge hole from the top plate toward the heater.

12. The prober according to claim 1, further comprising:
an air blower that sends the first gas toward the first flow path.

13. A prober comprising:
a support member for supporting a wafer, the support member including a first flow path through which a first gas passes and a second flow path merging with the first flow path;
a test part that tests electrical characteristics of semiconductor devices formed on the wafer when the wafer is placed on the support member;
a suction part that sucks the first gas from the second flow path; and
a cooling control part that instructs the suction part to or not to suck the first gas.

14. A wafer cooling method in a prober for testing electrical characteristics of semiconductor devices formed on a wafer, the prober including a support member that supports the wafer,
the support member including a first flow path through which a first gas passes and a second flow path merging with the first flow path,
the method comprising:
a step of determining whether or not to cause a second gas to jet out toward the second flow path on the basis of a temperature of the wafer; and
a step of causing the second gas to jet out toward the second flow path when jetting of the second gas is permitted.
